(19) United States
(12) Patent Application Publication
(10) Pub. No.: US 2025/0112126 A1
(43) Pub. Date: Apr. 3, 2025

(54) WIDE BANDGAP POWER DEVICES WITH LOW POWER LOOP INDUCTANCE

(71) Applicant: TEXAS INSTRUMENTS INCORPORATED, Dallas, TX (US)

(72) Inventors: Jie CHEN, Plano, TX (US); Sylvester ANKAMAH-KUSI, Dallas, TX (US); Rajen Manicon MURUGAN, Dallas, TX (US); Yong XIE, Plano, TX (US); Danny Lee BRIJA, Allen, TX (US)

(21) Appl. No.: 18/478,715

(22) Filed: Sep. 29, 2023

(51) Int. Cl. H01L 23/495; H01L 23/00; H01L 25/065; H01L 29/16; H01L 29/20; H01L 29/778

(52) U.S. Cl. CPC H01L 23/4951; H01L 23/4952; H01L 23/49589; H01L 24/32; H01L 24/48; H01L 24/73; H01L 25/0652; H10D 30/472; H10D 62/8325; H10D 62/8503; H01L 2224/32137; H01L 2224/32245; H01L 2224/48091; H01L 2224/48138; H01L 2224/73265; H01L 2924/1205; H01L 2924/13091

(57) ABSTRACT

In examples, a power device comprises a first wide bandgap semiconductor die including a high-side transistor; a second wide bandgap semiconductor die including a low-side transistor; and a conductive device coupled to the first and second wide bandgap semiconductor dies. The conductive device comprises a first layer including a first metal member having fingers at first and second ends of the first metal member, a second metal member having fingers interleaved with fingers of the first metal member at the first end, and a third metal member having fingers interleaved with fingers of the first metal member at the second end. The conductive device also comprises multiple layers in vertical alignment with the first layer, the first, second, and third metal members extending through the multiple layers. The conductive device also comprises a dielectric material covering the first layer and the multiple layers. The power device comprises a connection layer coupling the conductive device to each of the first and second wide bandgap semiconductor dies, with the connection layer including the first, second, and third metal members, and with the first metal member having connection layer fingers at the first and second ends of the first metal member. The second metal member has connection layer fingers interleaved with connection layer fingers of the first metal member at the first end, and the third metal member has connection layer fingers interleaved with connection layer fingers of the first metal member at the second end.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. Dies are then coupled to a lead frame and are covered by a mold compound, which is subsequently sawn to produce a package.

### SUMMARY

In examples, a power device comprises a first wide bandgap semiconductor die including a high-side transistor; a second wide bandgap semiconductor die including a low-side transistor; and a conductive device coupled to the first and second wide bandgap semiconductor dies. The conductive device comprises a first layer including a first metal member having fingers at first and second ends of the first metal member, a second metal member having fingers interleaved with fingers of the first metal member at the first end, and a third metal member having fingers interleaved with fingers of the first metal member at the second end. The conductive device also comprises multiple layers in vertical alignment with the first layer, the first, second, and third metal members extending through the multiple layers. The conductive device also comprises a dielectric material covering the first layer and the multiple layers. The power device comprises a connection layer coupling the conductive device to each of the first and second wide bandgap semiconductor dies, with the connection layer including the first, second, and third metal members, and with the first metal member having connection layer fingers at the first and second ends of the first metal member. The second metal member has connection layer fingers interleaved with connection layer fingers of the first metal member at the first end, and the third metal member has connection layer fingers interleaved with connection layer fingers of the first metal member at the second end.

A method of manufacturing a power device comprises iteratively plating portions of first, second, and third metal members and covering the portions with a dielectric material to form a conductive device having multiple layers through which the first, second, and third metal members extend. A first layer of the multiple layers includes fingers of the second metal member interleaved with first fingers of the first metal member to form a first interleaved structure and includes fingers of the third metal member interleaved with second fingers of the first metal member to form a second interleaved structure. The method also comprises coupling a capacitor to the second and third metal members; coupling a first wide bandgap semiconductor die to the first interleaved structure, the first wide bandgap semiconductor die including a first transistor; coupling a second wide bandgap semiconductor die to the second interleaved structure, the second wide bandgap semiconductor die including a second transistor; coupling the first and second wide bandgap semiconductor dies to a substrate; wire bonding the second and third metal members to the substrate; and covering the conductive device, the capacitor, the first and second semiconductor dies, and the substrate with a mold compound.

### BRIEF DESCRIPTION OF THE DRAWINGS

FIG. 1A is a top-down view of a wide bandgap power device with low power loop inductance, in accordance with various examples.

FIG. 1B is a perspective view of a wide bandgap power device with low power loop inductance, in accordance with various examples.

FIG. 1C is a profile view of a wide bandgap power device with low power loop inductance, in accordance with various examples.

FIG. 2A is a circuit diagram of a power device, in accordance with various examples.

FIG. 2B is a top-down view of a wide bandgap power device with low power loop inductance, in accordance with various examples.

FIGS. 2C-2F are profile views of a wide bandgap power device with low power loop inductance, in accordance with various examples.

FIG. 2G is a perspective view of a wide bandgap power device with low power loop inductance, in accordance with various examples.

FIG. 2H is a perspective view of a wide bandgap power device with low power loop inductance, in accordance with various examples.

FIG. 2I is a bottom-up view of a conductive device of a wide bandgap power device with low power loop inductance, in accordance with various examples.

FIGS. 3A-3E are top-down views of different layers of a conductive device of a wide bandgap power device with low power loop inductance, in accordance with various examples.

FIG. 4 is a flow diagram of a method for manufacturing a wide bandgap power device with low power loop inductance, in accordance with various examples.

FIGS. 5A-5M are a process flow of a method for manufacturing a wide bandgap power device with low power loop inductance, in accordance with various examples.

### DETAILED DESCRIPTION

Power circuits may include multiple transistors that are repeatedly switched on and off to provide power to one or more devices. An example power circuit may include a high-side transistor, such as a high-side field effect transistor (e.g., FET, such as a metal oxide semiconductor FET (MOSFET)), and a low-side transistor, such as a low-side FET (e.g., MOSFET). Each of the high-side and low-side transistors includes two current terminals (e.g., a source and a drain), as well as a control terminal (e.g., a gate). A first current terminal of the high-side FET is coupled to a voltage supply, also known as a voltage rail. A second current terminal of the high-side FET is coupled to a first current terminal of the low-side FET. A second current terminal of the low-side FET is coupled to ground. The control terminals of the high-side and low-side FETs are coupled to a controller, such as gate driver circuitry. The node at which the high-side and low-side FETs couple to each other (e.g., the connection between the second current terminal of the high-side FET and the first current terminal of the low-side FET) may be called the switching node or switch node (“SW node”). The SW node provides the output of the power circuit. The SW node may be coupled to another device or other circuitry that receives power from the power circuit. The power circuit may also include a coupling capacitor coupled between the voltage rail and the ground terminal. The electrical pathway including the coupling capacitor, the voltage rail, the high-side FET, the SW node, the low-side FET, and the ground terminal may be referred to as the “power loop” of the power circuit.

Parts of the power circuit are formed using semiconductors. For example, each of the high-side and low-side FETs may be formed in a separate semiconductor die. Different semiconductors have different properties. Certain types of semiconductors, such as gallium nitride and silicon carbide, are wide bandgap (i.e., semiconductors with bandgaps above 2 electronvolts (eV)) devices and may be useful to form switching FETs due to their favorable properties, such as high breakdown voltage (which enables the FETs to handle higher power levels), as well as high operating temperatures and high electron mobility (which enable the FETs to switch faster). To realize faster switching speeds, however, the inductance of the power loop should be low, because inductance is a measure of resistance to change in current, and high switching speeds require low resistance to changes in current. Because wide bandgap devices tend to be large in physical size, the length of the power loop tends to be high, and thus the inductance of the power loop also tends to be high. As explained above, large power loop inductances (which may be referred to as parasitic inductance) are not conducive to fast switching speeds, thus presenting a bottleneck that prevents the switching speed benefits of wide bandgap devices from being fully realized. Not only do these high power loop parasitic inductances present a bottleneck to switching speed, but they can also cause large voltage spikes during switch turn off, which can cause functional and even mechanical failures.

This disclosure describes various examples of a power device that presents technical solutions to the technical challenges described above. In examples, a power device includes a first wide bandgap semiconductor die including a high-side transistor and a second wide bandgap semiconductor die including a low-side transistor. The power device comprises a conductive device coupled to the first and second wide bandgap semiconductor dies. The conductive device comprises a first layer including a first metal member having fingers at first and second ends of the first metal member, a second metal member having fingers interleaved with fingers of the first metal member at the first end, and a third metal member having fingers interleaved with fingers of the first metal member at the second end. The conductive device includes multiple layers in vertical alignment with the first layer, the first, second, and third metal members extending through the multiple layers. The conductive device includes a dielectric material covering the first layer and the multiple layers. The power device includes a connection layer coupling the conductive device to each of the first and second wide bandgap semiconductor dies. The connection layer includes the first, second, and third metal members, with the first metal member having connection layer fingers at the first and second ends of the first metal member, the second metal member having connection layer fingers interleaved with connection layer fingers of the first metal member at the first end, and the third metal member having connection layer fingers interleaved with connection layer fingers of the first metal member at the second end. These and other examples are now described with reference to the drawings.

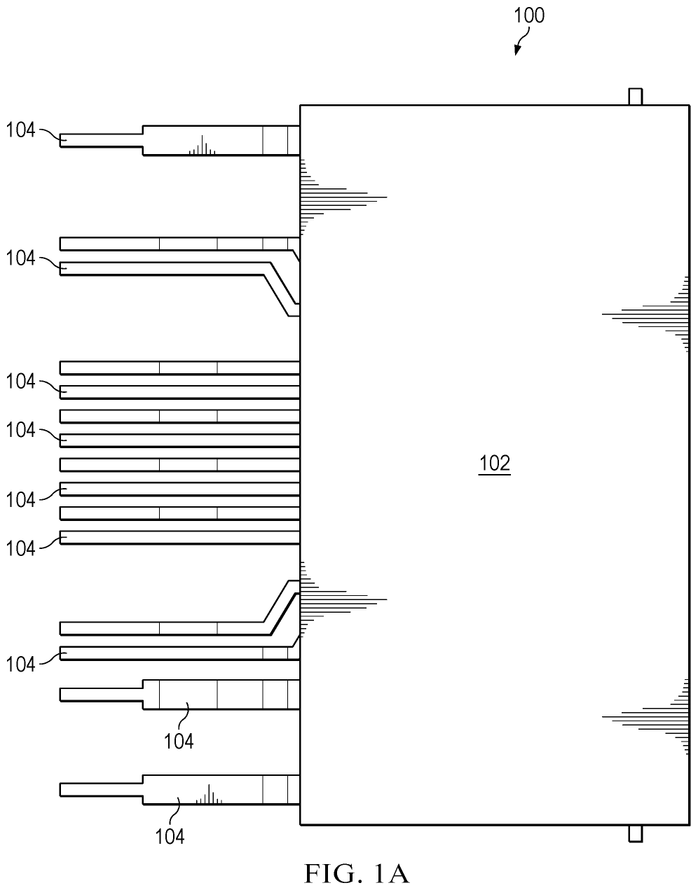

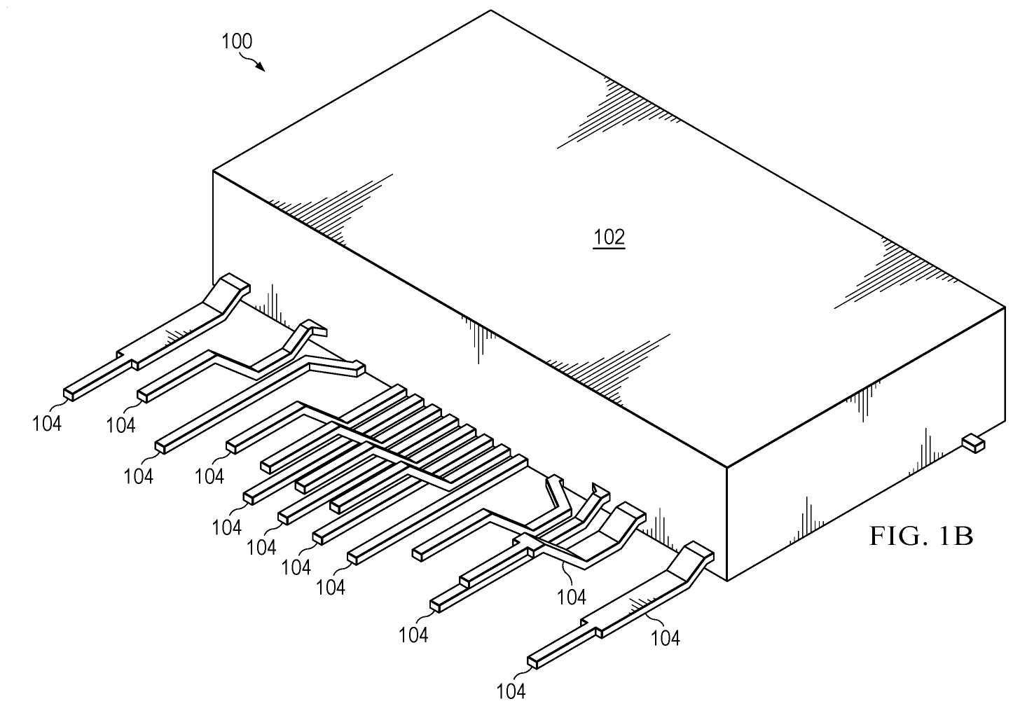

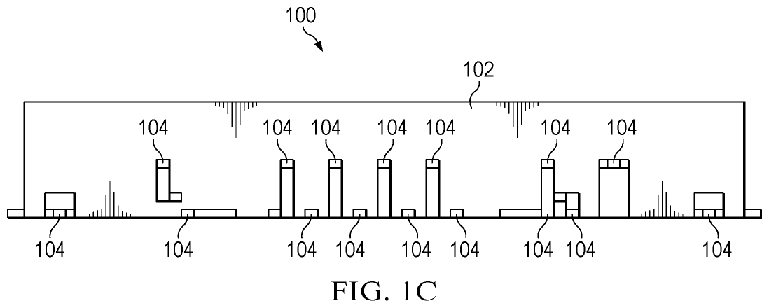

FIG. 1A is a top-down view of a wide bandgap power device 100 with low power loop inductance, in accordance with various examples. The power device 100 may also be referred to herein as a package 100. The power device 100 includes a mold compound 102 that covers various components of the power device 100, such as switching transistors, that are described below. Conductive terminals 104 emerge from within the mold compound 102 and extend away from the mold compound 102. Different conductive terminals 104 may be configured to carry different types of electrical signals and/or power. For example, larger conductive terminals 104 may be useful to carry power, while smaller conductive terminals 104 may be useful to carry data signals. The conductive terminals 104 may also be referred to herein as pins 104 or leads 104. FIG. 1B is a perspective view of the power device 100, in accordance with various examples. FIG. 1C is a profile view of the power device 100, in accordance with various examples.

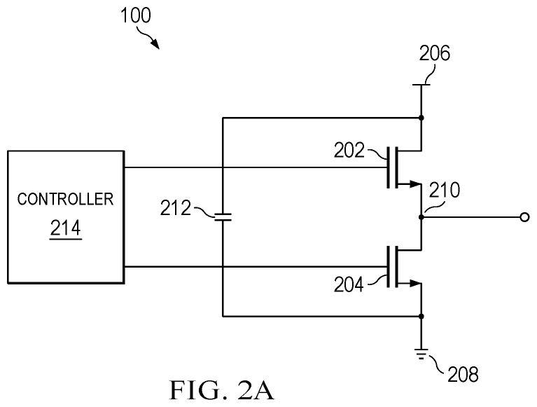

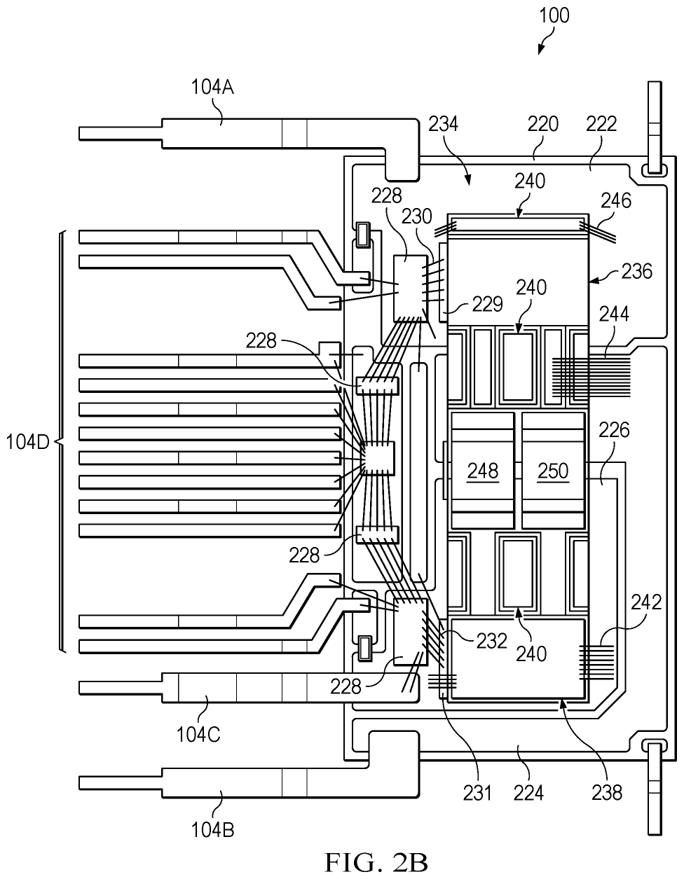

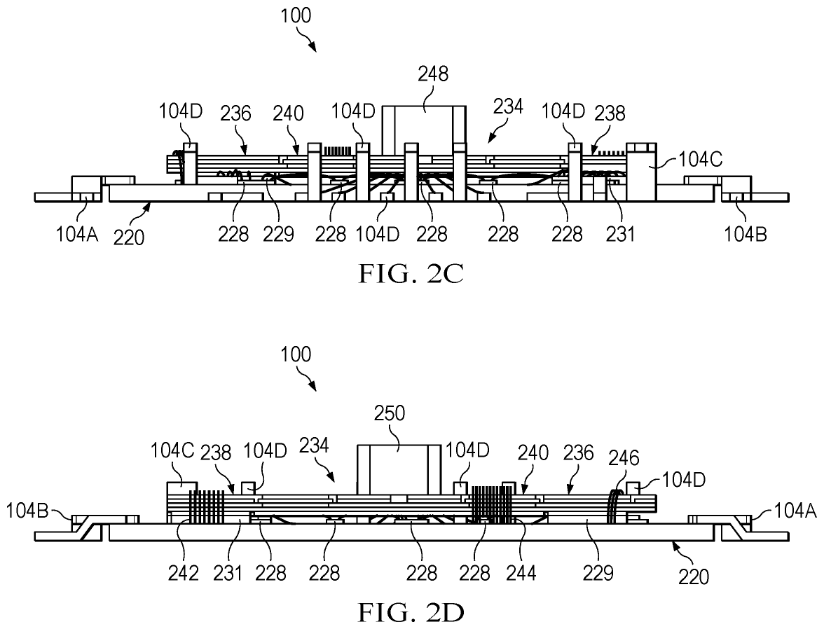

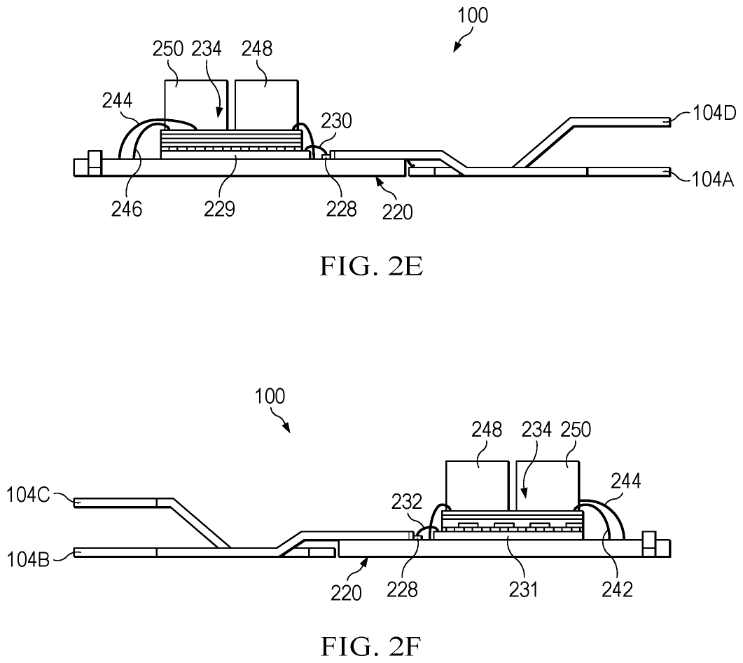

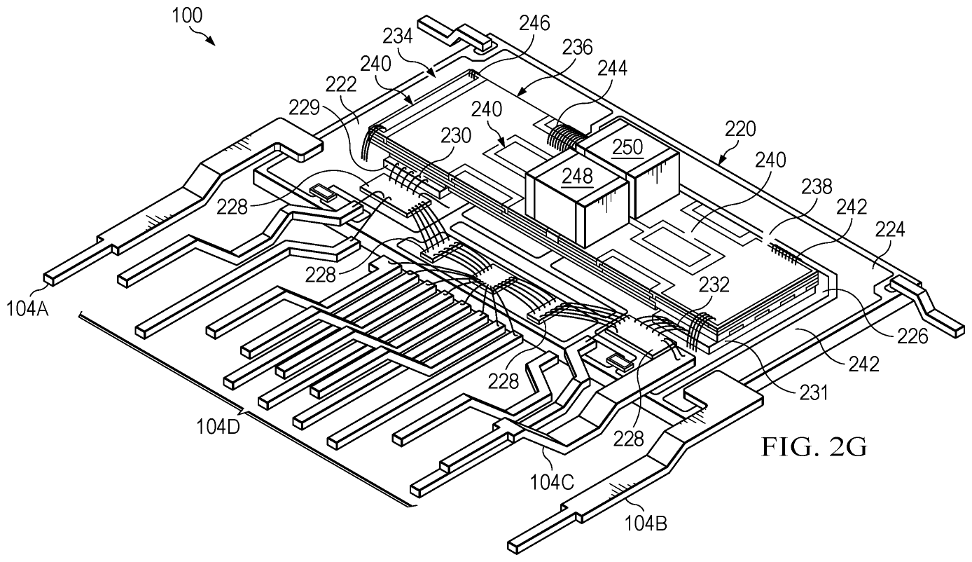

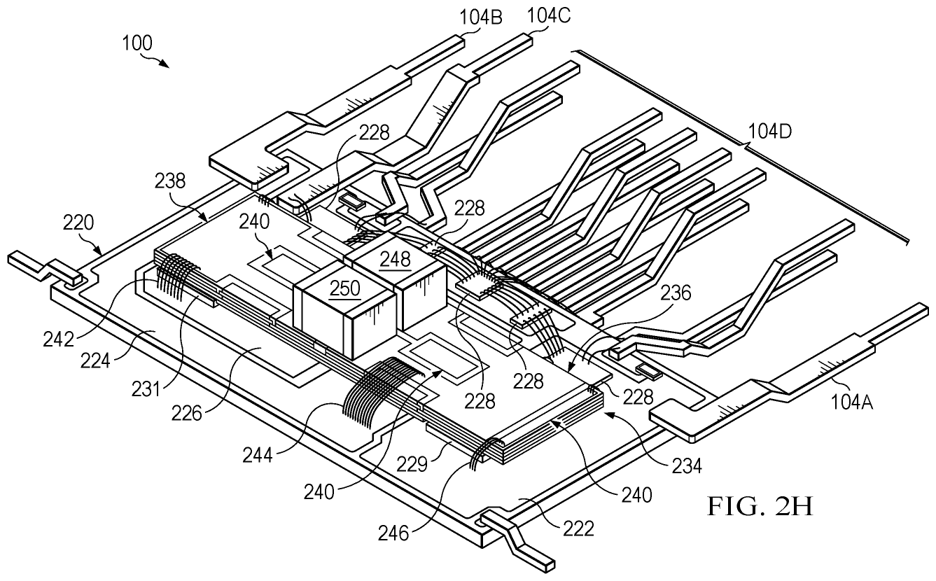

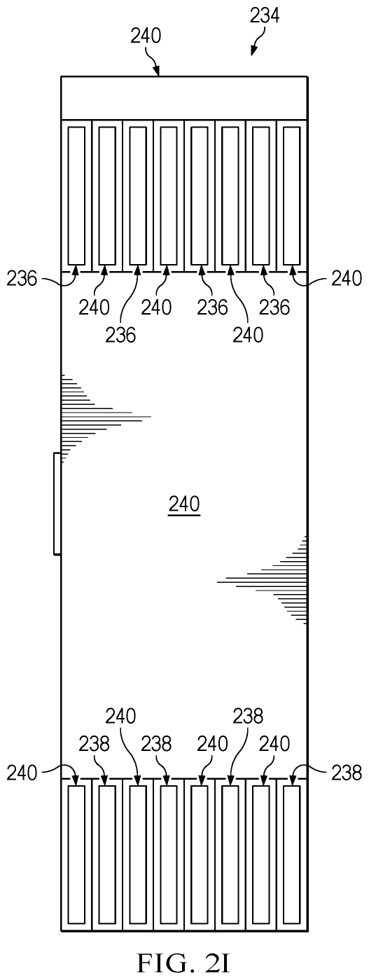

FIG. 2A is a circuit diagram of the power device 100, in accordance with various examples. The power device 100 may include a transistor 202, such as a FET (e.g., MOSFET, n-type FET/MOSFET, p-type FET/MOSFET), and a transistor 204, such as a FET (e.g., MOSFET, n-type FET/MOSFET, p-type FET/MOSFET). The transistor 202 may be referred to as a high-side transistor, because the transistor 202 is configured to provide power from a voltage supply 206 when the transistor 202 is on and a channel has formed. Conversely, the transistor 204 may be referred to as a low-side transistor, because the transistor 204 is configured to provide a connection to a ground terminal 208 when the transistor 204 is on and a channel has formed. A node 210, which may be referred to as a SW node 210, is coupled between the transistor 202 and 204, for example to a source terminal of the transistor 202 and a drain terminal of the transistor 204. A coupling capacitor 212 is coupled to the transistor 202 (e.g., to a drain of the transistor 202) and to the transistor 204 (e.g., to a source of the transistor 204). A controller 214, which may include a gate driver, is coupled to control terminals of the transistors 202, 204, such as to gate terminals of the transistors 202, 204.

In operation, the controller 214 outputs voltages to the transistors 202, 204 causing the transistor 202 to turn on and the transistor 204 to turn off. Consequently, the SW node 210 is pulled up to the voltage provided by voltage supply 206. The controller 214 then outputs voltages to the transistors 202, 204 causing the transistor 202 to turn off and the transistor 204 to turn on. Consequently, the SW node 210 is pulled down to ground provided by the ground terminal 208. The controller 214 rapidly switches back and forth between these states, causing the transistors 202, 204 to switch on and off, thereby causing the SW node 210 to alternate between high and low voltage states. The power device 100 includes a power loop comprising the transistor 202, SW node 210, transistor 204, and coupling capacitor 212. The structural implementation of the circuit of FIG. 2A in the power device 100 produces a low power loop inductance, as described below.

FIG. 2B is a top-down view of the power device 100, in accordance with various examples. The power device 100 includes a substrate 220 (e.g., a thermally conductive, electrically insulative substrate, such as a ceramic substrate) having conductive surfaces positioned thereupon. For example, the substrate 220 and its conductive surfaces may be referred to herein as a direct bonded copper (DBC) substrate or layer. The conductive surfaces of the substrate 220 include conductive surfaces 222, 224, and 226. Conductive surface 222 is coupled to a conductive terminal 104A and, as described below, corresponds to the SW node 210 in FIG. 2A. Conductive surface 224 is coupled to a conductive terminal 104B and, as described below, corresponds to voltage supply 206 in FIG. 2A. Conductive surface 226 is coupled to a conductive terminal 104C and, as described below, corresponds to ground terminal 208 in FIG. 2A. The power device 100 includes various control circuitry 228, which may correspond to the controller 214 of FIG. 2A. The power device 100 includes a semiconductor die 229 (comprising a wide bandgap semiconductor material such as gallium nitride or silicon carbide), which includes a transistor that corresponds to the high-side transistor 202. The power device 100 includes a semiconductor die 231 (comprising a wide bandgap semiconductor material, such as gallium nitride or silicon carbide, which specifically refers to semiconductor materials with bandgaps above 2 electronvolts (eV)), which includes a transistor that corresponds to the low-side transistor 204. In the view of FIG. 2B, the dies 229, 231 are partially obscured.

Bond wires 230 are useful to couple control circuitry 228 to the semiconductor die 229, such as to a gate terminal of the semiconductor die 229. Bond wires 232 are useful to couple control circuitry 228 to the semiconductor die 231, such as to a gate terminal of the semiconductor die 231.

The power device 100 includes a conductive device 234. The conductive device 234 is configured to provide power from the voltage supply 206 (FIG. 2A) to the semiconductor die 229, which includes transistor 202 (FIG. 2A). Similarly, the conductive device 234 is configured to provide ground from the ground terminal 208 (FIG. 2A) to the semiconductor die 231, which includes transistor 204 (FIG. 2A). Further, the conductive device 234 is configured to couple the transistors 202, 204 (FIG. 2A) to each other, thereby embodying the SW node 210 (FIG. 2A) and to couple the semiconductor dies 229, 231 (and, thus, transistors 202, 204 in FIG. 2A) to each other. The conductive device 234 includes a metal member 236, a metal member 238, and a metal member 240. The metal member 236 embodies the node between the voltage supply 206 and the transistor 202. The metal member 238 embodies the node between the ground terminal 208 and the transistor 204. The metal member 240 embodies the SW node 210. Bond wires 242 couple the metal member 238 to the conductive surface 226. Bond wires 244 couple the metal member 236 to the conductive surface 224. Bond wires 246 couple the metal member 240 to the conductive surface 222. Coupling capacitors 248, 250 couple the metal member 236 to the metal member 238.

FIGS. 2C-2F are profile views of the power device 100, in accordance with various examples. FIG. 2G is a perspective view of the power device 100, in accordance with various examples. FIG. 2H is a perspective view of the power device 100, in accordance with various examples. FIG. 2I is a bottom-up view of the power device 100, in accordance with various examples.

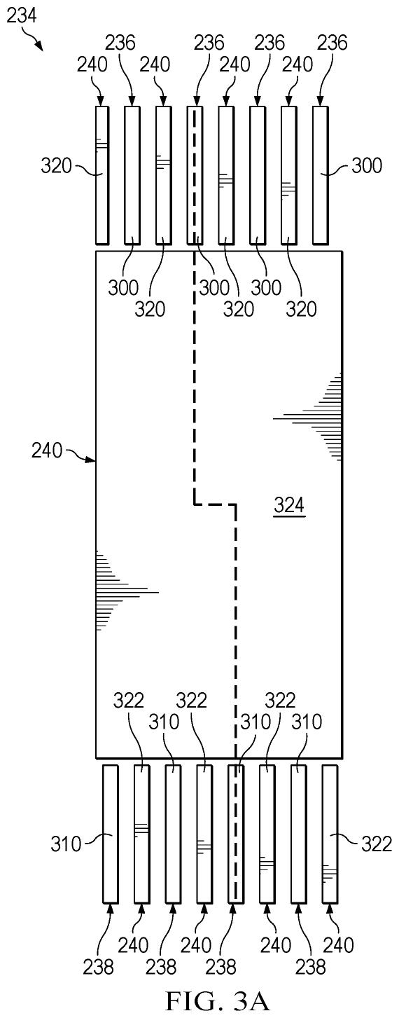

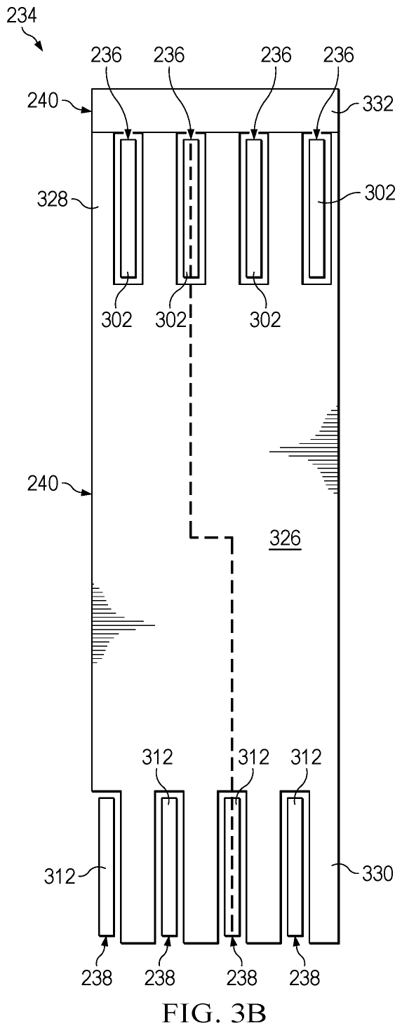

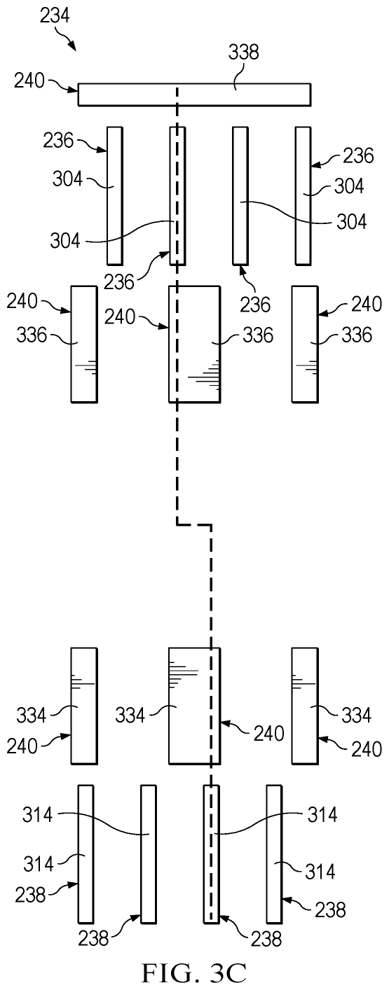

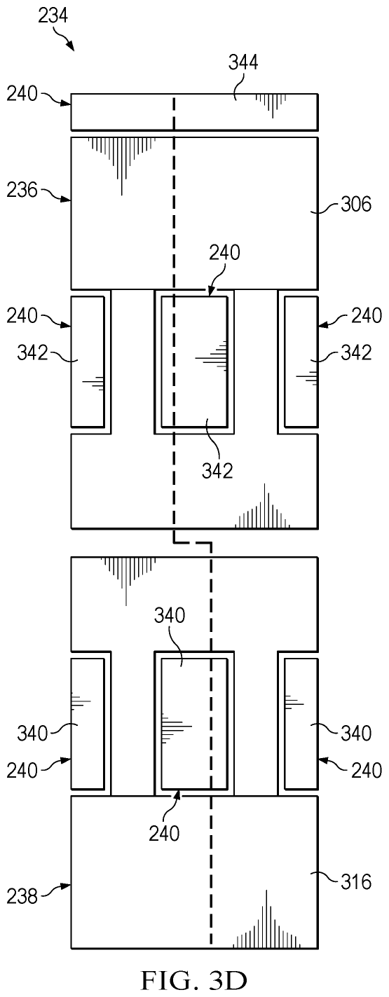

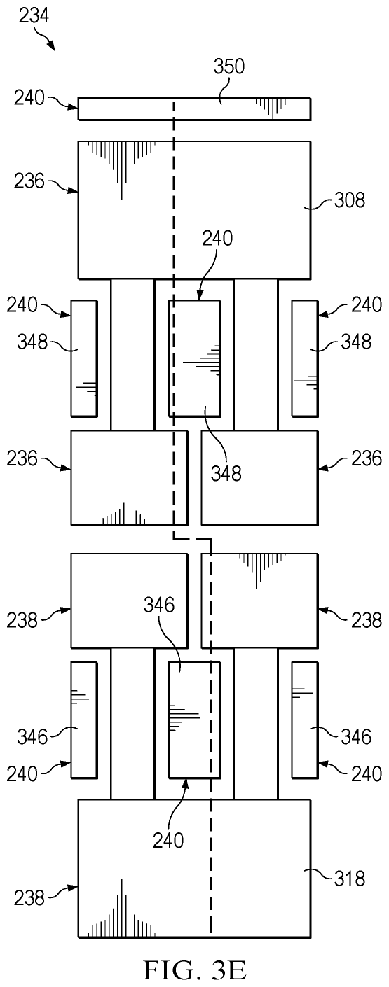

FIGS. 3A-3E are top-down views of different layers of the conductive device 234, in accordance with various examples. FIG. 3A shows the bottom-most layer of the conductive device 234, which abuts the semiconductor dies 229, 231 (FIG. 2B). FIG. 3B shows a layer immediately adjacent to the bottom-most layer of FIG. 3A; FIG. 3C shows the layer abutting the layer of FIG. 3B; FIG. 3D shows the layer abutting the layer of FIG. 3C; and FIG. 3E, which abuts the layer of FIG. 3D, is the top-most layer of the conductive device 234 and is most easily visible in FIG. 2B. The conductive device 234 includes the metal members 236, 238, and 240, each of which extends through the various layers shown in FIGS. 3A-3E. For example, the metal member 236 includes fingers 300 in the layer of FIG. 3A, fingers 302 in the layer of FIG. 3B that are coupled to the fingers 300 shown in FIG. 3A, fingers 304 in the layer of FIG. 3C that are coupled to the fingers 302 shown in FIG. 3B; a portion 306 in the layer of FIG. 3D that couples to the fingers 304 shown in FIG. 3C; and a portion 308 in the layer of FIG. 3E that couples to the portion 306 shown in FIG. 3D. In this manner, the metal member 236 extends vertically from the bottom-most layer shown in FIG. 3A, through each of the layers shown in FIGS. 3B-3D, to the top-most layer shown in FIG. 3E.

Still referring to FIGS. 3A-3E, the metal member 238 includes fingers 310 in the bottom-most layer of FIG. 3A; fingers 312 in the layer of FIG. 3B that are coupled to the fingers 310 shown in FIG. 3A; fingers 314 in the layer of FIG. 3C that are coupled to the fingers 312 shown in FIG. 3B; a portion 316 in the layer of FIG. 3D that couples to the fingers 314 shown in FIG. 3C; and a portion 318 in the layer of FIG. 3E that couples to the portion 316 shown in FIG. 3D. In this manner, the metal member 238 extends vertically from the bottom-most layer shown in FIG. 3A, through each of the layers shown in FIGS. 3B-3D, to the top-most layer shown in FIG. 3E.

In the bottom-most layer shown in FIG. 3A, the metal member 240 includes fingers 320 and 322 and a portion 324 that is positioned between the fingers 320 and 322. In the layer of FIG. 3B, the metal member 240 includes a portion 326 and fingers 328 and fingers 330 on opposing ends of the portion 326, as well as a portion 332 coupled to the fingers 328. The various components of metal member 240 shown in FIG. 3B connect to the components of metal member 240 shown in FIG. 3A. In the layer of FIG. 3C, the metal member 240 includes portions 334, 336, and 338, all of which couple to the components of metal member 240 shown in FIG. 3B. In the layer of FIG. 3D, the metal member 240 includes portions 340, 342, and 344, all of which couple to the components of metal member 240 shown in FIG. 3C. In the layer of FIG. 3E, the metal member 240 includes portions 346, 348, and 350, all of which couple to the components of metal member 240 shown in FIG. 3D. In this manner, the metal member 240 extends vertically from the bottom-most layer shown in FIG. 3A, through each of the layers shown in FIGS. 3B-3D, to the top-most layer shown in FIG. 3E. As shown in FIGS. 3A-3E, to maintain electrical isolation from each other, the metal members 236, 238, and 240 do not contact each other at any level of the conductive device 234.

Still referring to FIGS. 3A-3E, the fingers 300 are interleaved with the fingers 320. Similarly, the fingers 310 and interleaved with the fingers 322. This interleaving of different metal members 236, 238, and 240 results in increased mutual inductance. Parasitic inductance in one of the fingers is mitigated by the parasitic inductance in a next consecutive finger. For example, the parasitic inductance in a finger 300 is mitigated by the parasitic inductance in an adjacent finger 320. Similarly, the parasitic inductance in a finger 310 is mitigated by the parasitic inductance in an adjacent finger 322. This interleaving of multiple fingers in the layer of FIG. 3A results in a diminished total parasitic inductance in the power loop of the power device 100. In the layer of FIG. 3B, the fingers 302 and 328 are similarly interleaved, as are the fingers 312 and 330. In the layer of FIG. 3D, the portions 342 extend through the portion 306, which results in mitigation of the parasitic inductance of the power loop, as described above. Similarly, in the layer of FIG. 3D, the portions 340 extend through the portion 316, which results in mitigation of the parasitic inductance of the power loop, as described above. Similarly, in the layer of FIG. 3E, the portions 348 extend through the portion 308, and the portions 346 extend through the portion 318, thus mitigating the parasitic inductance of the power loop, as described above.

In FIG. 3A, the fingers 300 have widths ranging from 30 microns to 60 microns. Widths within this range are critical to minimize inductance and resistance (and thus to improve Q-factor). The fingers 310 and 320 have dimensions identical to those of the fingers 300, and these dimensions are critical for the same reasons provided above. The pitch between interleaved fingers, such as the fingers 300 interleaved with fingers 320, and the fingers 310 interleaved with the fingers 322, ranges from 30 microns to 60 microns. A pitch within this range is critical to establish tight coupling (i.e., tight spacing) that is adequate to increase mutual inductance and reduce loop inductance. In FIG. 3B, the fingers 328 have widths ranging from 30 microns to 60 microns. Widths within this range are critical to minimize inductance and resistance (and thus to improve Q-factor). The fingers 330 have dimensions identical to those of the fingers 328, and these dimensions are critical for the same reasons provided above. The fingers 302, 312 have dimensions identical to those of the fingers 300, 310, respectively, and these dimensions are critical for the same reasons provided above. In FIG. 3C, the fingers 304, 314 have physical dimensions identical to those of the fingers depicted in FIGS. 3A and 3B, and these dimensions are critical for the same reasons provided above.

Referring to FIGS. 2A-3E, in operation, the controller 214 may cause the high-side transistor 202 formed in the semiconductor die 229 to turn on and the low-side transistor 204 in the semiconductor die 231 to turn off. To accomplish this, the control circuitry 228 provides the appropriate signals to the semiconductor dies 229, 231 via the bond wires 230, 232, respectively. In response, the semiconductor die 229 shorts the fingers 300, 320, and the semiconductor die 231 does not short the fingers 310, 322. By shorting the fingers 300, 320, the SW node 210 (which corresponds to metal member 240 and thus to fingers 320) is coupled to the voltage supply 206, pulling the SW node 210 up to the voltage of the voltage supply 206. Stated another way, the metal members 236, 240 are coupled together, so that the SW node 210 and the voltage supply 206 are coupled together. Current flows in opposing directions in the fingers 300 relative to the fingers 320 (i.e., opposing directions in space), thus increasing mutual inductance and mitigating total parasitic inductance. For example, current may flow through the fingers 300 toward the die 229, and then from the die 229 through the fingers 320, thus causing the current to flow through the fingers 300 in one direction in space and through the fingers 320 in an opposite direction in space. The metal member 238, however, is electrically isolated from the metal members 236, 240. As described above, mutual inductance is significantly increased by the interleaving patterns included in the layers shown in FIGS. 3A-3E. Thus, the reductions in parasitic inductance described above by having current flow in opposing directions (i.e., opposing directions in space) is also realized in other layers with such interleaving, as shown in FIGS. 3A-3E.

Further, in operation, the controller 214 may cause the high-side transistor 202 formed in the semiconductor die 229 to turn off and the low-side transistor 204 in the semiconductor die 231 to turn on. To accomplish this, the control circuitry 228 provides the appropriate signals to the semiconductor dies 229, 231 via the bond wires 230, 232, respectively. In response, the semiconductor die 229 does not short the fingers 300, 320, and the semiconductor die 231 shorts the fingers 310, 322. By shorting the fingers 310, 322, the SW node 210 (which corresponds to metal member 240 and thus to fingers 322) is coupled to the ground terminal 208, pulling the SW node 210 down to ground. Stated another way, the metal members 238, 240 are coupled together, so that the SW node 210 and the ground terminal 208 are coupled together. Current flows in opposing directions in the fingers 310, 322 (i.e., opposing directions in space), thus increasing mutual inductance and mitigating total parasitic inductance. The metal member 236, however, is electrically isolated from the metal members 238, 240. As described above, mutual inductance is significantly increased by the interleaving patterns included in the layers shown in FIGS. 3A-3E. Thus, the reductions in parasitic inductance described above by having current flow in opposing directions (i.e., opposing directions in space) is also realized in other layers with such interleaving, as shown in FIGS. 3A-3E.

The interleaving pattern is present in multiple layers of the conductive device 234, as shown in FIGS. 3A-3E. Each of these interleaving components increases mutual inductance, thereby mitigating parasitic inductance in the power loop of the power device 100. By reducing parasitic inductance, the bottleneck described above to many of the benefits of wide bandgap semiconductor devices (e.g., switching speed, improved power loss, fewer and lower voltage spikes) is mitigated or removed.

The mutual inductance is also increased by tightly coupling the layers (e.g., FIGS. 3A-3E) of the conductive device 234. The distance between the layer of FIG. 3A and the layer of FIG. 3C (i.e., the thickness of the layer in FIG. 3B) is no more than 65 microns. A distance greater than 65 microns results in unacceptably low mutual inductance and unacceptably poor mitigation of parasitic inductance. Similarly, the distance between the layers of FIGS. 3B and 3D and between the layers of FIGS. 3C and 3E is no more than 65 microns each, with a greater distance resulting in unacceptably low mutual inductance and unacceptably poor mitigation of parasitic inductance. By reducing parasitic inductance, the bottleneck described above to many of the benefits of wide bandgap semiconductor devices (e.g., switching speed, improved power loss, fewer and lower voltage spikes) is mitigated or removed.

In examples, the layer of FIG. 3A is considered to be part of the conductive device 234. In such examples, the layers of FIGS. 3A-3E form the conductive device 234. In other examples, the layer of FIG. 3A is considered to be separate from the conductive device 234. In such examples, the layers of FIGS. 3B-3E form the conductive device 234, with the layer of FIG. 3A serving as a connection layer coupling the conductive device 234 to the underlying semiconductor dies 229, 231. The structures are the same irrespective of nomenclature and are depicted in the drawings.

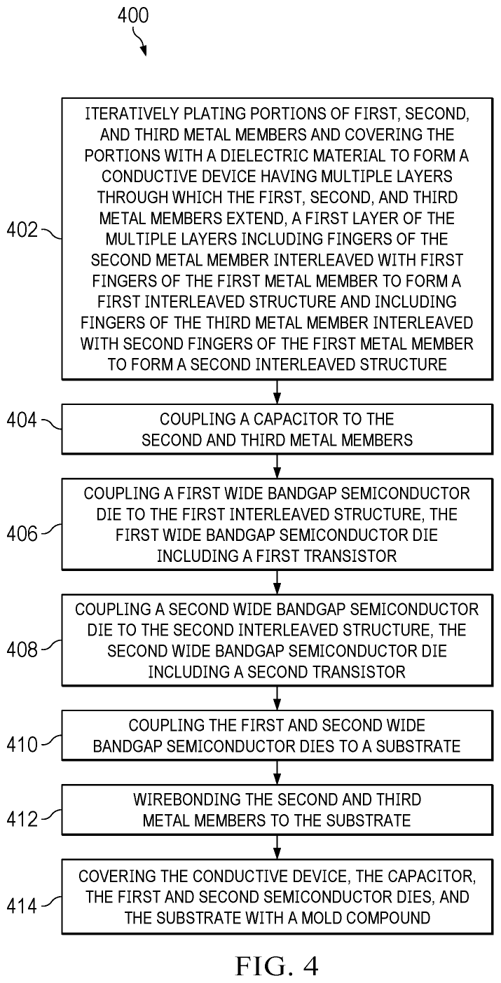

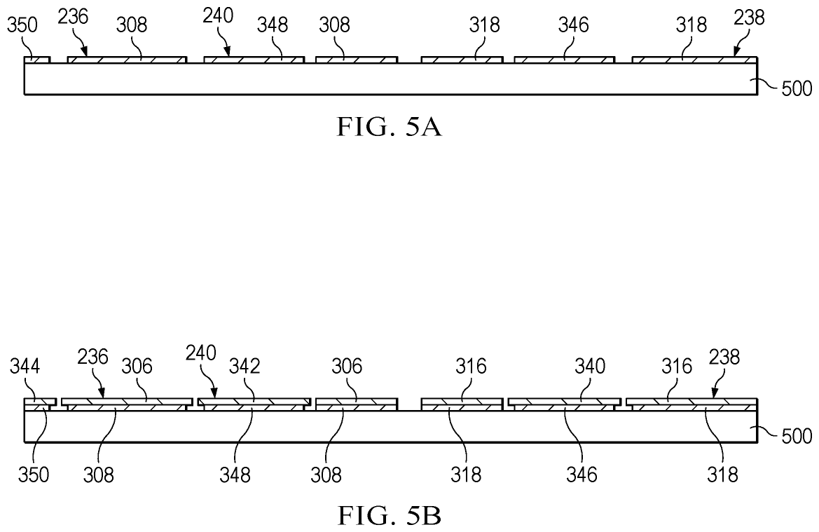

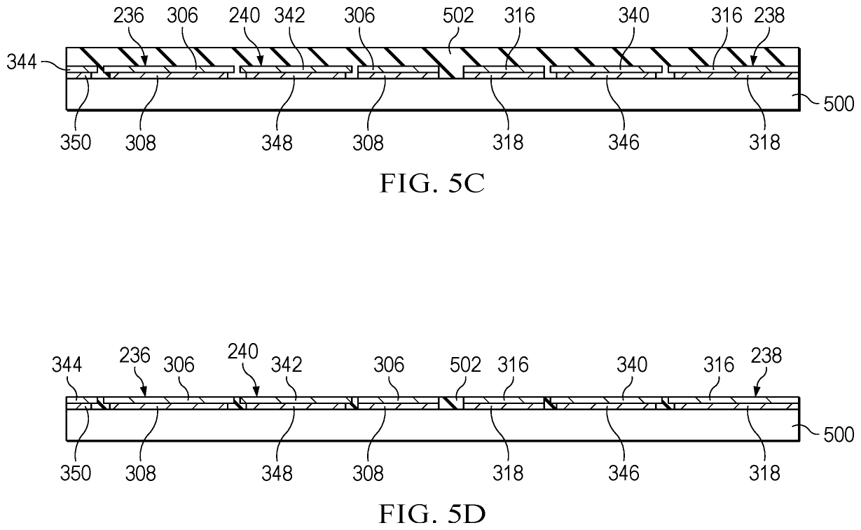

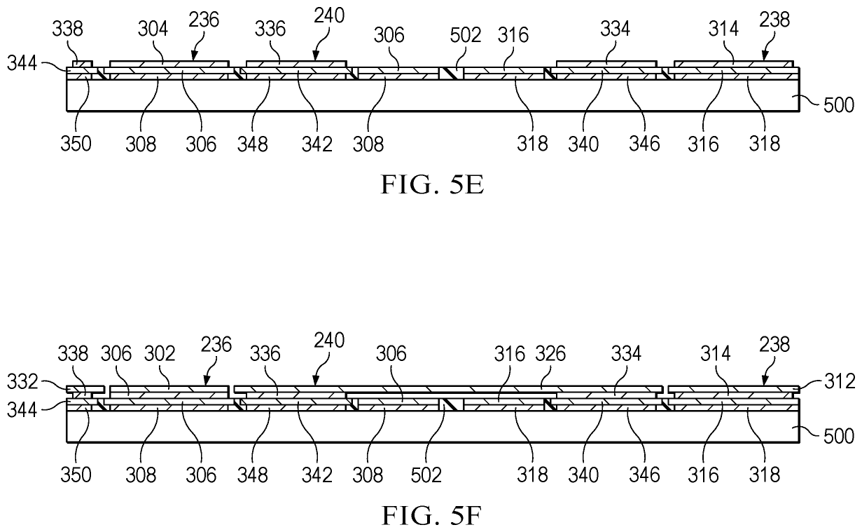

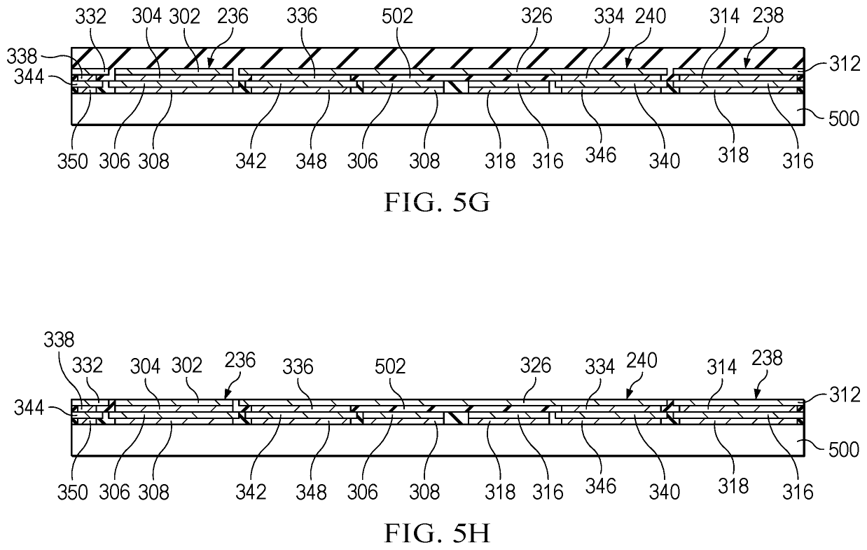

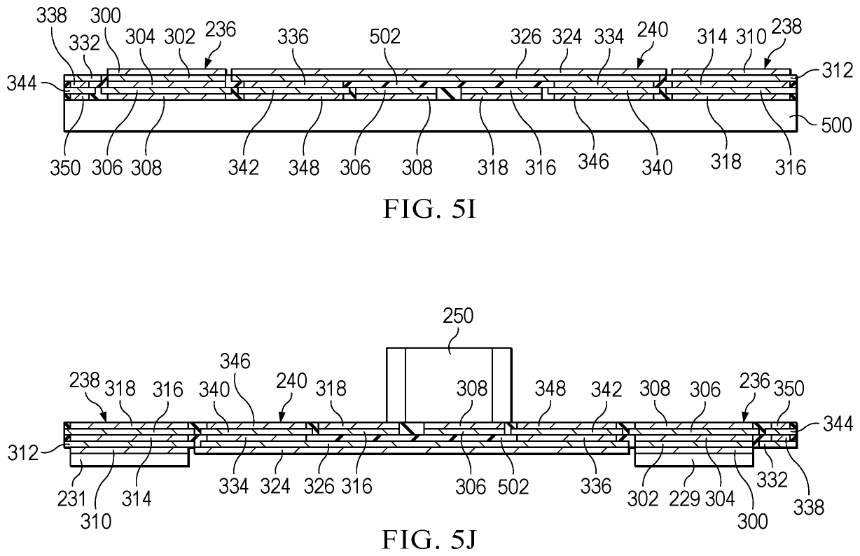

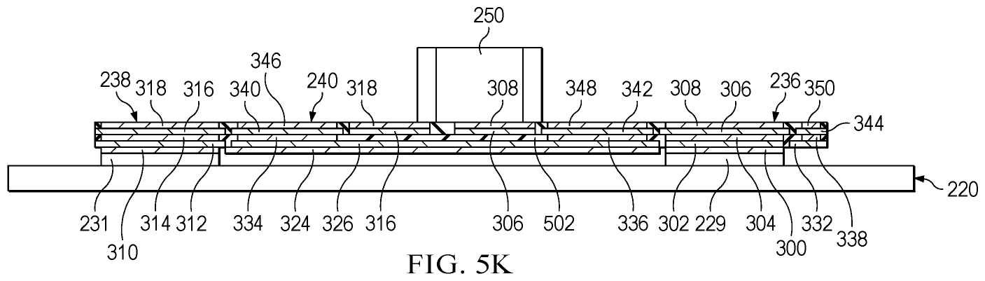

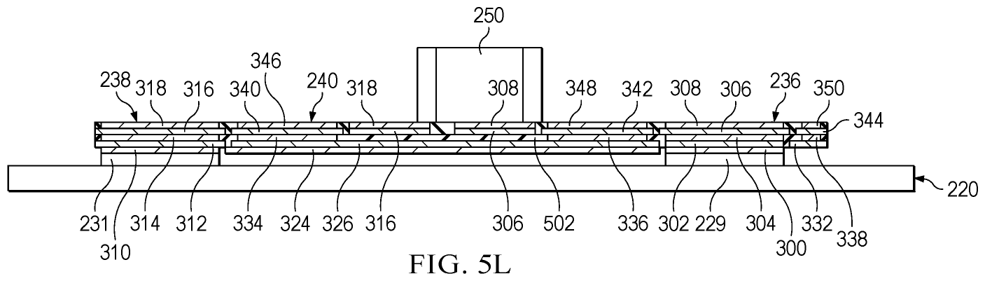

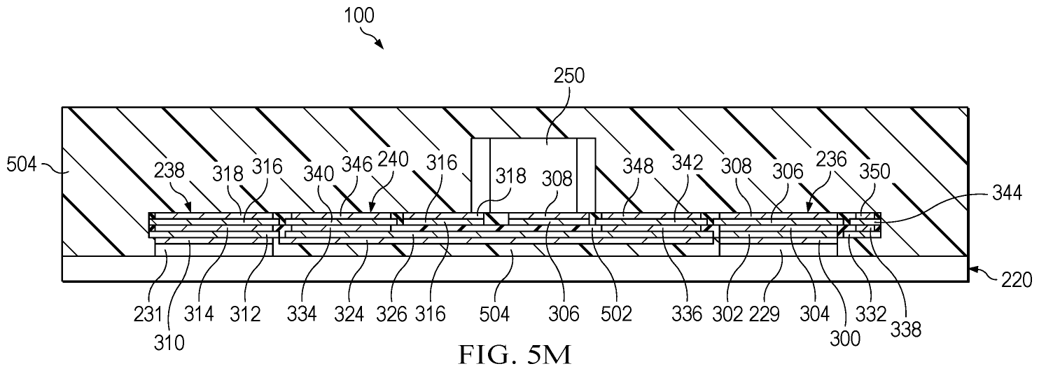

FIG. 4 is a flow diagram of a method 400 for manufacturing a wide bandgap power device with low power loop inductance, in accordance with various examples. FIGS. 5A-5M are a process flow of a method for manufacturing a wide bandgap power device with low power loop inductance, in accordance with various examples. The metal structures shown in FIGS. 5A-5M and a mold compound or other dielectric film covering and/or filling these metal structures together constitute a multi-layer package component that is the conductive device 234. A multi-layer package component is defined as a component of a semiconductor package, where the component includes multiple metal layers formed by electroplating and that further includes a dielectric such as a mold compound or film (e.g., AJINOMOTO® build-up film (ABF)) filling spaces between and around the multiple metal layers. The multiple metal layers form a network to route signals and/or power between various locations within the package 100. A multi-layer package component differs from a printed circuit board (PCB) because the multi-layer package component is within the package 100, whereas the PCB is outside the package 100. The multi-layer package component includes multiple metal layers that are separated by a solid, tangible dielectric, whereas the PCB may contain multiple layers of printed circuit board that may not be separated by a dielectric material other than air. Accordingly, FIGS. 5A-5M provide various views of such a multi-layer package component, such as the conductive device 234, within the semiconductor package 100, in accordance with various examples. The views of FIGS. 5A-5M are taken along the cross-sectional lines shown in FIGS. 3A-3E. Accordingly, FIGS. 4 and 5A-5M are now described in parallel.

The method 400 begins with iteratively plating portions of first, second, and third metal members and covering the portions with a dielectric material to form a conductive device having multiple layers through which the first, second, and third metal members extend (402). A first layer of the multiple layers includes fingers of the second metal member interleaved with first fingers of the first metal member to form a first interleaved structure and including fingers of the third metal member interleaved with second fingers of the first metal member to form a second interleaved structure (402).

FIG. 5A is a profile, cross-sectional view of a substrate 500 on which the metal members 236, 238, 240 of the layer in FIG. 3E are formed, for example, by electroplating. FIG. 5B is a profile, cross-sectional view of the metal members 236, 238, 240 of the layer in FIG. 3D being formed, for example, by electroplating. In FIG. 5C, a dielectric material 502, such as AJINOMOTO® build-up film (ABF), is applied to the structure of FIG. 5B. In FIG. 5D, the dielectric material 502 is grinded such that the top surface of the dielectric material 502 is approximately flush with the top surfaces of the metal members in the layer shown in FIG. 3D.

In FIG. 5E, the metal members 236, 238, 240 of the layer in FIG. 3C are formed, such as by electroplating, and in FIG. 5F, the metal members 236, 238, 240 of the layer in FIG. 3B are formed, such as by electroplating. In FIG. 5G, additional dielectric material 502 is deposited, and in FIG. 5H, the additional dielectric material 502 is grinded such that the top surface of the additional dielectric material 502 is approximately flush with the top surfaces of the metal members in the layer shown in FIG. 3B.

In FIG. 5I, the metal members 236, 238, 240 of the layer in FIG. 3A are formed, such as by electroplating.

The method 400 comprises coupling a capacitor to the second and third metal members (404). In FIG. 5J, the coupling capacitor 250 (visible in FIG. 5J) and the coupling capacitor 248 (not visible in FIG. 5J) are coupled to the metal members 236, 238.

The method 400 comprises coupling a first wide bandgap semiconductor die to the first interleaved structure, with the first wide bandgap semiconductor die including a first transistor (406). The method 400 also comprises coupling a second wide bandgap semiconductor die to the second interleaved structure, with the second wide bandgap semiconductor die including a second transistor (408). The method 400 includes coupling the first and second wide bandgap semiconductor dies to a substrate (410), such as a direct bonded copper substrate including a ceramic component and conductive surfaces formed thereupon or applied thereto. In FIG. 5K, the semiconductor dies 229, 231 are coupled to the metal members 236, 238, 240 in the layer of FIG. 3A, and the dies 229, 231 are coupled to the substrate 220, such as a direct bonded copper substrate including a ceramic component and conductive surfaces formed thereupon or applied thereto.

The method 400 also comprises wire bonding the second and third metal members to the substrate (412). In FIG. 5L, bond wires 242, 244, and 246 (described above with reference to FIG. 2B, and not expressly visible in FIG. 5L due to the cross-section taken) are applied. The method 400 also comprises covering the conductive device, the capacitors, the first and second semiconductor dies, and the substrate with a mold compound (414). In FIG. 5M, a mold compound 504 is applied to cover the structures of FIG. 5L, thereby producing a completed package (i.e., power device 100).

The conductive device 234 (i.e., the layers of FIGS. 3A-3E or 3B-3E) formed by the method 400 differs from a printed circuit board (PCB) because the conductive device 234 is within a semiconductor package (e.g., the package shown in FIG. 5M), whereas a PCB is outside the package. The conductive device 234 includes multiple metal layers that are covered by a solid, tangible dielectric material 502, whereas the PCB may contain multiple layers of printed circuit board that may not be separated by a dielectric material other than air.

As described above, the examples described herein provide significant technical benefits:

| Property | Power device 100 | | Baseline solution | |
|---|---|---|---|---|
| Power loop inductance (in | 0.565 | | 2.225 | |
| nanohenries (nH)) | | | | |
| Direct current (DC) resistance | For voltage | For ground | For voltage | For ground |
| (in milli Ohms) | supply-SW | terminal-SW | supply-SW | terminal-SW |
| | node path: | node path: | node path: | node path: |
| | 3.94 | 2.83 | 4.71 | 3.56 |

| | | |
|---|---|---|
| Common source inductance | Close to zero | 100 picohenries (pH) |

As shown in the table above, the power loop inductance for the power device 100 is approximately 25% of the power loop inductance of the baseline solution. This results in various technical benefits, such as mitigated voltage spikes and the damage they cause. In addition, the DC resistance of the power loop of the power device 100 is 83.6% and 79.5% of the baseline values for the voltage supply-SW node path and ground terminal-SW node path, respectively. This results in various technical benefits, such as reduced power loss.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Uses of the term “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. A power device, comprising:
a first wide bandgap semiconductor die including a high-side transistor;
a second wide bandgap semiconductor die including a low-side transistor;
a conductive device coupled to the first and second wide bandgap semiconductor dies, the conductive device comprising:
a first layer including a first metal member having fingers at first and second ends of the first metal member, a second metal member having fingers interleaved with fingers of the first metal member at the first end, and a third metal member having fingers interleaved with fingers of the first metal member at the second end;
multiple layers in vertical alignment with the first layer, the first, second, and third metal members extending through the multiple layers; and
a dielectric material covering the first layer and the multiple layers; and
a connection layer coupling the conductive device to each of the first and second wide bandgap semiconductor dies, the connection layer including the first, second, and third metal members, the first metal member having connection layer fingers at the first and second ends of the first metal member, the second metal member having connection layer fingers interleaved with connection layer fingers of the first metal member at the first end, and the third metal member having connection layer fingers interleaved with connection layer fingers of the first metal member at the second end.

2. The power device of claim 1, wherein the multiple layers include second and third layers, the second layer in between and contacting the first and third layers, the second layer separating the first layer from the third layer by no more than 65 microns.

3. The power device of claim 1, further comprising a capacitor coupled to the second and third metal members.

4. The power device of claim 1, wherein the dielectric material is not air.

5. The power device of claim 1, wherein the first wide bandgap semiconductor die is configured to electrically short the first and second metal members to each other.

6. The power device of claim 1, wherein the second wide bandgap semiconductor die is configured to electrically short the first and third metal members to each other.

7. The power device of claim 1, further comprising a first substrate wirebonded to the second metal member and a second substrate separate from the first substrate and wirebonded to the third metal member.

8. The power device of claim 1, further comprising a gate driver circuit wirebonded to a control terminal of the high-side transistor and to a control terminal of the low-side transistor.

9. The power device of claim 1, wherein each of the first and second wide bandgap semiconductor dies comprise one of gallium nitride and silicon carbide.

10. A power device, comprising:
a first semiconductor die comprising gallium nitride or silicon carbide and including a high-side transistor formed therein;
a second semiconductor die comprising gallium nitride or silicon carbide and including a low-side transistor formed therein; and
a conductive device coupled to the first and second semiconductor dies, the conductive device including multiple layers and first, second, and third metal members extending through the multiple layers, a first layer of the multiple layers that is most proximal to the first and second semiconductor dies including fingers of the second metal member that are interleaved with first fingers of the first metal member and including fingers of the third metal member that are interleaved with second fingers of the first metal member, the conductive device including a dielectric material covering the first, second, and third metal members,
wherein a second layer of the multiple layers contacts the first layer and has a thickness less than or equal to 65 microns.

11. The power device of claim 10, further comprising a capacitor coupled to the second and third metal members.

12. The power device of claim 10, wherein the dielectric material is not air.

13. The power device of claim 10, wherein the first and second metal members are interleaved with each other in the multiple layers.

14. The power device of claim 10, wherein the first and third metal members are interleaved with each other in the multiple layers.

15. The power device of claim 10, wherein the first semiconductor die is configured to electrically short the first and second metal members together, and wherein the second semiconductor die is configured to electrically short the first and third metal members together.

16. A method of manufacturing a power device, comprising:
iteratively plating portions of first, second, and third metal members and covering the portions with a dielectric material to form a conductive device having multiple layers through which the first, second, and third metal members extend, a first layer of the multiple layers including fingers of the second metal member interleaved with first fingers of the first metal member to form a first interleaved structure and including fingers of the third metal member interleaved with second fingers of the first metal member to form a second interleaved structure;
coupling a capacitor to the second and third metal members;
coupling a first wide bandgap semiconductor die to the first interleaved structure, the first wide bandgap semiconductor die including a first transistor;
coupling a second wide bandgap semiconductor die to the second interleaved structure, the second wide bandgap semiconductor die including a second transistor;
coupling the first and second wide bandgap semiconductor dies to a substrate;
wirebonding the second and third metal members to the substrate; and
covering the conductive device, the capacitor, the first and second semiconductor dies, and the substrate with a mold compound.

17. The method of claim 16, wherein the dielectric material is not air.

18. The method of claim 16, wherein the first and second metal members are interleaved with each other throughout the multiple layers, and wherein the first and third metal members are interleaved with each other throughout the multiple layers.

19. The method of claim 16, wherein the multiple layers include second and third layers, the second layer between and contacting the first and third layers, the second layer separating the first and third layers by no more than 65 microns.

20. The method of claim 16, wherein each of the first and second wide bandgap semiconductor dies comprises gallium nitride or silicon carbide.
